(19) United States
(12) Patent Application Publication
(10) Pub. No.: US 2015/0357996 A1
(43) Pub. Date: Dec. 10, 2015

(54) RADIO RECEIVING DEVICE AND METHOD FOR SWITCHING FREQUENCIES OF RADIO STATIONS

(71) Applicants: Yung-Chang Hu, Taipei City (TW); Wei-En Chang, Taipei City (TW); Wei-Yu Cheng, Taipei City (TW)

(72) Inventors: Yung-Chang Hu, Taipei City (TW); Wei-En Chang, Taipei City (TW); Wei-Yu Cheng, Taipei City (TW)

(73) Assignee: COMPAL ELECTRONICS, INC., Taipei City (TW)

(21) Appl. No.: 14/457,137

(22) Filed: Aug. 12, 2014

(30) Foreign Application Priority Data
Jun. 5, 2014 (TW) 103119592

(51) Int. Cl. H03J 7/18

(52) U.S. Cl. CPC H03J 7/183

(57) ABSTRACT

A radio receiving device, including a positioning module, a radio receiver, a speaker device, and a control unit, and a method of switching frequencies of radio stations are provided. The positioning module obtains a geographic location of the radio receiving device. The radio receiver plays radio information through the speaker device at a first frequency of a radio. The control unit detects a first signal strength of the radio information at the first frequency. When the first signal strength is smaller than a default value, the control unit checks a radio network frequency list according to the geographic location to obtain a second frequency, and detects a second signal strength of the radio information at the second frequency. When the second signal strength is larger than the first signal strength, the radio receiver plays the radio information through the speaker device at the second frequency of the radio.

### CROSS-REFERENCE TO RELATED APPLICATION

This application claims the priority benefit of Taiwan application serial no. 103119592, filed on Jun. 5, 2014. The entirety of the above-mentioned patent application is hereby incorporated by reference herein and made a part of this specification.

### BACKGROUND OF THE INVENTION

1. Field of the Invention

The invention relates to signal receiving technology for radio stations and particularly relates to a radio receiving device that can be installed in a vehicle (e.g. an automobile) and a method of switching frequencies of radio stations.

2. Description of Related Art

Generally, radio stations transmit audio information, e.g. broadcasts, in a wireless and unidirectional manner for a distant radio receiver to receive the broadcasts from the radio stations at specific frequencies. However, one radio station may send different regional broadcasts in different regions, or the radio station may not have the same radio frequency in all the regions. As a result, the frequency of the radio station may differ from region to region.

Reception of the radio installed in a vehicle may be easily affected by the movement of the vehicle. Such a problem becomes worse when the vehicle moves in an area where the signal of the radio station is relatively weak or in a border area between several radio stations. Therefore, in the situation that the vehicle is in the border area between two radio stations of different frequencies and the signals from the radio stations are both weak, how to automatically adjust the frequency to maintain the reception of the radio is an issue that needs to be solved.

### SUMMARY OF THE INVENTION

The invention provides a radio receiving device and a method of switching frequencies of radio stations for continuously detecting reception of the radio station at different frequencies and automatically switching to another radio frequency with better signal strength according to a geographic location of the radio receiving device when the current reception is very poor, so as to avoid the problem that a vehicle provided with the radio receiving device cannot automatically switch to a better radio frequency when the vehicle is in a border area between two radio stations and receives the same radio.

The invention provides a radio receiving device, which includes a positioning module, a radio receiver, a speaker device, and a control unit. The positioning module is configured to obtain a geographic location of the radio receiving device. The speaker device is coupled to the radio receiver. The control unit is coupled to the positioning module and the radio receiver. The radio receiver receives radio information at a first frequency of a radio and plays the radio information through the speaker device. The control unit detects a first signal strength of the radio information at the first frequency. When the first signal strength is smaller than a default value, the control unit checks a radio network frequency list according to geographic location information to obtain a second frequency of the radio corresponding to the geographic location information. The control unit detects a second signal strength of the radio information at the second frequency. When the second signal strength is larger than the first signal strength, the control unit controls the radio receiver to receive the radio information at the second frequency of the radio and play the radio information through the speaker device.

From another aspect, the invention provides a radio frequency switching method including the following: receiving radio information at a first frequency of a radio and playing the radio information; detecting a first signal strength of the radio information at the first frequency and determining whether the first signal strength is smaller than a default value; obtaining geographic location information through a positioning module and checking a radio network frequency list according to the geographic location information to obtain a second frequency of the radio corresponding to the geographic location information when the first signal strength is smaller than the default value. The radio network frequency list includes a plurality of radio names, a plurality of geographic areas respectively corresponding to the radio names, and frequencies respectively corresponding to the radio names in the geographic areas; detecting a second signal strength of the radio information at the second frequency; and receiving the radio information at the second frequency of the radio and playing the radio information when the second signal strength is larger than the first signal strength.

In an embodiment of the invention, the radio frequency switching method further includes the following: maintaining receiving the radio information at the first frequency and playing the radio information when unable to check the radio network frequency list according to the geographic location information to obtain the second frequency corresponding to the radio.

Based on the above, the radio receiving device and the radio frequency switching method of the embodiments of the invention are adapted to continuously detecting the signal strength of the radio signal that is currently received. When the signal strength is very low, another frequency of the radio in the geographic location is obtained according to the geographic location and the radio network frequency list of the radio receiving device for determining whether the signal strength at the another frequency is larger than the original signal strength. If the signal strength received at the another frequency is larger than the original signal strength, the radio is received at the another frequency. In other words, the radio receiving device of the embodiment of the invention, installed in a vehicle (e.g. an automobile), continuously detects the radio reception and automatically switches to a better frequency according to the geographic location only when the current reception is very poor, so as to prevent the problem that the vehicle cannot automatically switch to the better frequency when the vehicle is in a border area between two radio stations that play the same radio information.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a function block diagram illustrating a radio receiving device according to an embodiment of the invention.

FIG. 2 is a schematic view illustrating a situation where a vehicle provided with the radio receiving device is in a border area between radio stations according to an embodiment of the invention.

FIG. 3 is a flowchart illustrating a method of switching frequencies of radio stations according to an embodiment of the invention.

### DESCRIPTION OF THE EMBODIMENTS

In order that a radio receiving device can automatically adjust the frequency according to the geographic location detected by the positioning module to maintain the reception of the radio receiving device, the embodiments of the invention continuously detect the radio reception and switch to a better radio frequency according to the geographic location only when the current reception is very poor, thereby avoiding the problem that a vehicle provided with the radio receiving device cannot automatically switch to the radio frequency with better reception when receiving the same radio information in a border area between two radio stations. Details of embodiments are provided below to support the concept of the embodiments of the invention.

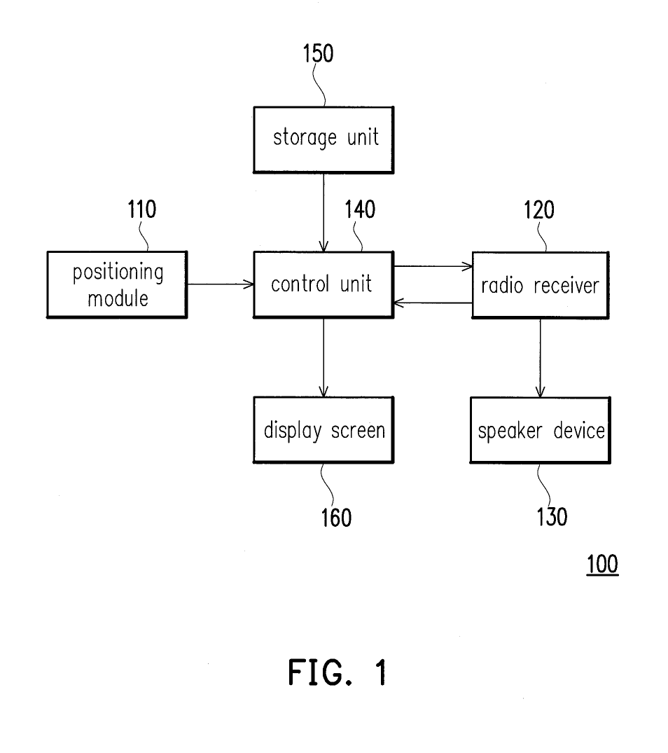

FIG. 1 is a function block diagram illustrating a radio receiving device 100 according to an embodiment of the invention. The radio receiving device 100 is adapted to be installed in a vehicle, such as an automobile, a boat, etc. The radio receiving device 100 may also be installed in a mobile device, such as a smart phone, a laptop computer, etc. As shown in FIG. 1, the radio receiving device 100 mainly includes a positioning module 110, a radio receiver 120, a speaker device 130, and a control unit 140. The positioning module 110 is configured to obtain a geographic location of the radio receiving device 100. In this embodiment, the positioning module 110 may be positioning equipment implemented by a global positioning system (GPS) or Wi-Fi positioning technology. Those who apply this embodiment should be able to use the technology for obtaining a geographic location of the radio receiving device 100 in the positioning module 110. However, it should be noted that the invention is not limited to the above.

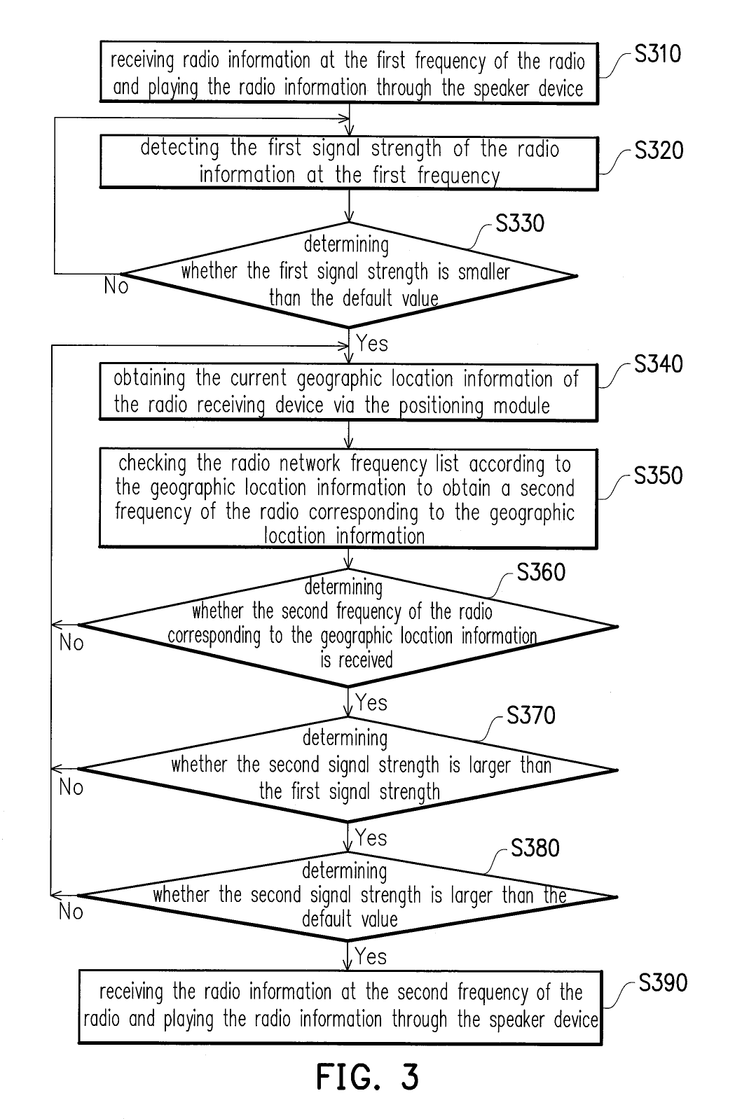

The radio receiver 120 may include a frequency regulator. The speaker device 130 is coupled to the radio receiver 120 for playing an audio signal received by the radio receiver 120. In this embodiment, the speaker device 130 may be audio equipment of a vehicle or speaker equipment of a mobile device. The control unit 140 may be a logical unit, such as a central processing unit, a special-purpose integrated circuit, a complex programmable logic device (CPLD), etc., for implementing a radio frequency switching method shown in FIG. 3. The control unit 140 of this embodiment communicates with the radio receiver 120 and the positioning module 110 via a chip hardware communication interface (e.g., I2C). An operation of the control unit 140 is described in detail in the following embodiment.

The radio receiving device 100 further includes a display screen 160 and a storage unit 150. The display screen 160 is coupled to the control unit 140 for displaying an operational interface for controlling the control unit 140. The user may control the control unit 140 through the operational interface on the display screen 160. The storage unit 150 is coupled to the control unit 140 for storing a radio network frequency list. The radio network frequency list may include a plurality of radio names, a plurality of geographic areas respectively corresponding to the radio names, and frequencies respectively corresponding to the radios in the geographic areas. Table 1 is an example of the radio network frequency list.

TABLE 1

| Radio name | Geographic area | Radio frequency |
|---|---|---|
| Police Broadcasting Service | Taipei | FM 104.9 |
| National Traffic Network | | |
| Police Broadcasting Service | Miaoli | FM 105.1 |
| National Traffic Network | | |
| Police Broadcasting Service | Tainan | FM 104.9 |
| National Traffic Network | | |
| . . . | . . . | . . . |

In this embodiment, Table 1 exemplifies one radio (i.e. Police Broadcasting Service National Traffic Network). According to Table 1, if the user would like to listen to the radio “Police Broadcasting Service National Traffic Network” in Taipei or Tainan, the user needs to tune the radio receiving device 100 to FM 104.9; if the user would like to listen to the radio “Police Broadcasting Service National Traffic Network” in Miaoli, the user needs to tune the radio receiving device 100 to FM 105.1. Those who apply this embodiment should be able to integrate radio information of any region according to the format of the above Table 1 and store the radio information in the storage unit 150. It should be noted that the geographic area in Table 1 may include a geographic range represented by GPS coordinates. In that case, the control unit 150 may look up the “geographic area” column in Table 1 based on the current GPS coordinates of the radio receiving device 100 obtained by the positioning module 110 (i.e. the current geographic location) to determine the geographic area corresponding to the current geographic location.

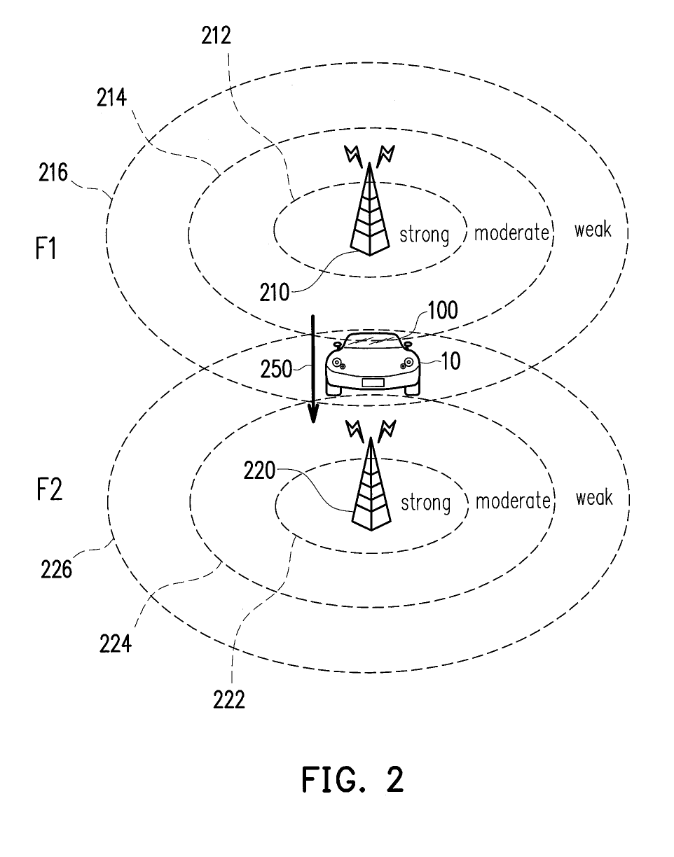

FIG. 2 is a schematic view illustrating a situation where a vehicle 10 provided with the radio receiving device 100 is in a border area between radio stations according to an embodiment of the invention. In FIG. 2, two radio transmitting stations 210 and 220 are provided for broadcasting the same radio. In this embodiment, the radio transmitting stations 210 and 220 are configured to broadcast the radio “Police Broadcasting Service National Traffic Network” in different areas, wherein a frequency of the radio transmitting station 210 is F1 and a frequency of the radio transmitting station 220 is F2. The radio transmitting stations 210 and 220 have different signal strength ranges depending on the signal strengths. For example, the radio receiving device 100 receives strong signal strength in a range 212 of the radio transmitting station 210 or in a range 222 of the radio transmitting station 220; the radio receiving device 100 receives moderate signal strength in a range 214 of the radio transmitting station 210 or in a range 224 of the radio transmitting station 220; and the radio receiving device 100 receives weak signal strength in a range 216 of the radio transmitting station 210 or in a range 226 of the radio transmitting station 220. Here it is provided that the vehicle 10 moves in a direction indicated by an arrow 250. A radio having a broadcast network has radio transmitting stations of different transmitting frequencies in different areas. In the situation of FIG. 2, the vehicle 10 receives the radio first at the frequency F1, and then the vehicle 10 gradually moves from the range 212 with strong signal strength toward the range 216 with weak signal strength and comes to the range 226 of the radio transmitting station 220 with the frequency F2. Traditionally, as the vehicle 10 gradually moves away from the radio transmitting station 210, the audio signal strength of the radio received at the frequency F1 gradually decreases until the audio signal eventually disappears or too much noise is generated, and then the user may manually tune the frequency to F2.

In the case that the control unit 140 automatically adjusts the reception frequency only based on the current geographic location provided by the positioning module 110, when the vehicle 10 moves to the border between the ranges 216 and 226 of the radio transmitting stations 210 and 220 and the frequencies F1 and F2 both provide weak signal strength, the reception of the radio may become worse after the frequency is switched. The reason is that the signal transmission at the border between the radio transmitting stations 210 and 220 may be affected by external conditions, such as the terrain, weather, and environment. If the reception frequency of the radio receiving device 100 is adjusted simply based on the geographic location information, the radio receiving device 100 may not obtain the better reception for the radio.

Accordingly, in the embodiments of the invention, the signal strength of the radio information at the current frequency is used as the main reference first, and the radio receiving device 100 obtains one or multiple other radio frequencies according to the current geographic location and detects whether the signal strength of the newly-obtained radio frequency is larger than the signal strength of the current radio frequency only when the control unit 140 detects that the signal strength of the radio information at the current frequency decreases to a certain degree. Thus, the radio frequency switching method of the embodiment of the invention is provided to prevent switching to a radio frequency having signal strength worse than the original radio frequency.

Details of operations of the radio receiving device 100 and the control unit 140 are described hereinafter. FIG. 3 is a flowchart illustrating a method of switching frequencies of radio stations according to an embodiment of the invention. Please refer to FIG. 1 and FIG. 3 and see FIG. 2 as an example. In Step S310, as the vehicle 10 moves in the direction of the arrow 250, the radio receiver 120 of the radio receiving device 100 receives the radio information at a first frequency of the radio (e.g. the frequency F1) and plays the radio information through the speaker device 130. In Step S320, the control unit 140 continuously detects a first signal strength of the radio information at the first frequency (the frequency F1). In Step S330, after the control unit 140 obtains the first signal strength, the control unit 140 compares the first signal strength with a default value to determine whether the first signal strength is smaller than the default value. If the first signal strength is not smaller than the default value, the control unit returns to Step S320 and continues detecting the signal strength of the radio information at the first frequency. Here, the “default value” is a minimum signal strength of the radio information at a specific frequency. If the signal strength is smaller than the default value, it indicates that the reception of the radio is poor and problems such as intermittence or interruption of the audio signal may occur.

If the first signal strength is smaller than the default value, Step S340 is performed after Step S330, and the control unit 140 obtains the current geographic location information of the radio receiving device 100 via the positioning module 110. In Step S350, the control unit 140 checks a radio network frequency list according to the geographic location information to obtain a second frequency of the radio corresponding to the geographic location information. In Step S360, the control unit 140 determines whether the second frequency of the radio corresponding to the current geographic location information is obtained. Take the embodiment of FIG. 2 for example, the control unit 140 confirms that the second frequency F2 is also available for receiving the radio in addition to the first frequency F1 according to the geographic location information and the radio network frequency list. If the, second frequency of the radio is not found, the control unit 140 may return to Step S340 from Step S360 to repeatedly check the radio network frequency list according to the current geographic location information.

On the other hand, if the second frequency of the radio is found, the control unit 140 moves on to Step S370 from Step S360 to detect a second signal strength of the radio information at the second frequency F2 and determine whether the second signal strength is larger than the first signal strength. If the second signal strength is larger than the first signal strength, the control unit 140 moves on to Step S380 from Step S370 and determines whether the second signal strength is larger than the default value. If the second signal strength is larger than the first signal strength and the default value, the control unit 140 moves on to Step S390 from Step S380 to control the radio receiver 120 to receive the radio information at the second frequency F2 of the radio and play the radio information through the speaker device 130.

If the second signal strength is larger than the first signal strength but smaller than the minimum signal strength, the control unit 140 returns to Step S340 from Step S380 to obtain the current geographic location information through the positioning module 110 again and check the radio network frequency list according to the geographic location information to obtain a third frequency of the radio corresponding to the geographic location information for replacing the second frequency and accordingly repeating Steps S340-S380. If the second signal strength is smaller than the first signal strength, the control unit 140 returns to Step S340 from Step S370 to obtain the current geographic location information through the positioning module 110 again so as to repeat Steps S340-S390.

It should be noted that the aforementioned Step 5380 may be added or removed from the flowchart according to the actual needs. The invention is not limited to the above descriptions. In other words, in other embodiments of the invention, whether the second signal strength is larger than the default value may not be determined in Step S380. In that case, Step S390 may be performed to execute the corresponding processes once Step S370 confirms that the second signal strength is larger than the first signal strength.

To conclude the above, the radio receiving device and the radio frequency switching method of the embodiments of the invention are adapted to continuously detecting the signal strength of the radio signal that is being received. When the signal strength is very low, another frequency of the radio in the geographic location is obtained according to the geographic location and the radio network frequency list of the radio receiving device for determining whether the signal strength received at the another frequency is larger than the original signal strength. If the signal strength received at the another frequency is larger than the original signal strength, the radio is received at the another frequency. In other words, the radio receiving device of the embodiment of the invention, installed in a vehicle (e.g. an automobile), continuously detects the radio reception and automatically switches to a better frequency according to the geographic location of the radio receiving device only when the current reception is very poor, so as to prevent the problem that the vehicle cannot automatically switch to the better frequency when the vehicle is in a border area between two radio stations.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. A radio receiving device, comprising:
a positioning module configured to obtain a geographic location of the radio receiving device;
a radio receiver;
a speaker device coupled to the radio receiver; and
a control unit coupled to the positioning module and the radio receiver, wherein
the radio receiver receives radio information at a first frequency of a radio and plays the radio information through the speaker device, and the control unit detects a first signal strength of the radio information at the first frequency, wherein the control unit checks a radio network frequency list according to geographic location information to obtain a second frequency of the radio corresponding to the geographic location information and detect a second signal strength of the radio information at the second frequency when the first signal strength is smaller than a default value, and the control unit controls the radio receiver to receive the radio information at the second frequency of the radio and plays the radio information through the speaker device when the second signal strength is larger than the first signal strength.

2. The radio receiving device according to claim 1, wherein the radio network frequency list comprises a plurality of radio names, a plurality of geographic areas respectively corresponding to the radio names, and a plurality of frequencies respectively corresponding to the radio names in the geographic areas, wherein the radio is one of the radio names.

3. The radio receiving device according to claim 1, further comprising:
a storage unit coupled to the control unit for storing the radio network frequency list.

4. The radio receiving device according to claim 1, further comprising:
a display screen coupled to the control unit for displaying an operational interface for controlling the control unit.

5. The radio receiving device according to claim 1, wherein the radio receiving device is installed in a vehicle.

6. The radio receiving device according to claim 1, wherein the control unit communicates with the radio receiver and the positioning module via a chip hardware communication interface, and the positioning module is a global positioning system.

7. The radio receiving device according to claim 1, wherein the control unit determines whether the second signal strength is larger than a minimum signal strength when the second signal strength is larger than the first signal strength; the control unit receives the radio information at the second frequency of the radio and plays the radio information through the speaker device when the second signal strength is larger than the first signal strength and the minimum signal strength; and the control unit obtains the current geographic location information through the positioning module again and checks the radio network frequency list according to the geographic location information to obtain a third frequency of the radio corresponding to the geographic location information so as to receive the radio information at the third frequency of the radio and play the radio information through the speaker device when the second signal strength is larger than the first signal strength but smaller than the minimum signal strength.

8. A radio frequency switching method, comprising:
receiving radio information at a first frequency of a radio and playing the radio information;
detecting a first signal strength of the radio information at the first frequency and determining whether the first signal strength is smaller than a default value;
obtaining geographic location information through a positioning module and checking a radio network frequency list according to the geographic location information to obtain a second frequency of the radio corresponding to the geographic location information when the first signal strength is smaller than the default value, wherein the radio network frequency list comprises a plurality of radio names, a plurality of geographic areas respectively corresponding to the radio names, and a plurality of frequencies respectively corresponding to the radio names in the geographic areas;
detecting a second signal strength of the radio information at the second frequency; and
receiving the radio information at the second frequency of the radio and playing the radio information when the second signal strength is larger than the first signal strength.

9. The radio frequency switching method according to claim 8, further comprising:
maintaining receiving the radio information at the first frequency and playing the radio information when unable to check the radio network frequency list according to the geographic location information to obtain the second frequency corresponding to the radio.

10. The radio frequency switching method according to claim 8, further comprising:
determining whether the second signal strength is larger than a minimum signal strength when the second signal strength is larger than the first signal strength;
receiving the radio information at the second frequency of the radio and playing the radio information when the second signal strength is larger than the first signal strength and the minimum signal strength; and
obtaining the current geographic location information through the positioning module again and checking the radio network frequency list according to the geographic location information to obtain a third frequency of the radio corresponding to the geographic location information when the second signal strength is larger than the first signal strength but smaller than the minimum signal strength.
